(19) United States
(12) Patent Application Publication
(10) Pub. No.: US 2026/0361304 A1
(43) Pub. Date: Nov. 12, 2026

(54) Substrate Voltage Stabilization Circuit, Pulldown Circuit and Gate Current Control Circuit for Semiconductor Devices Having a Bidirectional Switch

(71) Applicant: Infineon Technologies Austria AG, Villach (AT)

(72) Inventors: Francesco Sisti, Finkenstein am Faaker See (AT); Hyeongnam Kim, Chandler, AZ (US); Gerhard Maderbacher, Gleisdorf (AT); Herwig Wappis, Villach (AT); Alexander Young, Scottsdale, AZ (US); Ziyang Xiao, Phoenix, AZ (US); Jingcun Liu, Chandler, AZ (US); Mohamed Imam, Tempe, AZ (US)

(21) Appl. No.: 19/668,129

(22) Filed: May 5, 2026

Related U.S. Application Data
(60) Provisional application No. 63/800,704, filed on May 6, 2025.

(51) Int. Cl. H03K 17/687; H10D 30/47

(52) U.S. Cl. CPC H03K 17/687; H10D 30/471

(57) ABSTRACT

A semiconductor device includes: a terminal; a current driven HEMT (high electron mobility transistor) electrically connected to the terminal and having a gate diode; and a gate current control circuit configured to maintain the gate diode of the current driven HEMT at a voltage that is below a forward voltage of the gate diode while the terminal remains at a higher voltage and transitions to a lower voltage. Semiconductor device embodiments with a substrate voltage stabilization circuit and a pulldown circuit are also described.

### BACKGROUND

Two separate gates with a common drain in a monolithic device is a popular configuration for realizing a bidirectional switch. The monolithic device is typically implemented in a common substrate, where each of the two gates has its own gate driver. The common drain configuration has a source at either end of the monolithic device, meaning that a source connection to the substrate is not an option for the bidirectional switch. If the substrate is kept floating and one of the two sources is biased at a high voltage, that source in conjunction with the adjacent gate acts as an extended drain and thus follows the high potential. The substrate must be kept as close to ground potential during on-state as possible for stable bidirectional device operation. This can be achieved by ‘shorting’ the substrate to the lower of the source voltages with the help of a minimum-voltage-selector circuit. However, GIT (gate injection transistor) GaN technology presents a unique challenge.

GIT-based GaN technology uses an ohmic gate contact (instead of a Schottky gate contact) that is non-insulated and thus very rugged against over-voltage, due to the self-clamping nature of the equivalent diode (also referred to herein as gate diode) between the gate and channel. However, GIT-based bidirectional switches with a conventional substrate clamping design are less efficient and less robustness that what is expected. The root cause for this is that high voltage enhancement mode HEMTs (high electron mobility transistors) remain at a sub-threshold or near-threshold region. For example, for an off gate voltage Vgs,off of 0.5V, the gate of an enhancement mode HEMT remains at a sub-threshold or near-threshold voltage of ~1V, where the threshold Vth is ~1.2V during the voltage blocking state, leading to power loss and possibly thermal runaway. Biasing the gate of a GIT HEMT without causing the gate diode to conduct is challenging.

### SUMMARY

According to an embodiment of a semiconductor device, the semiconductor device comprises: a semiconductor body comprising an active region and a substrate region; a bidirectional switch comprising a first and a second gate structure each configured to control a conductive state of an electrically conductive channel in the active region; a first and a second input-output terminal each electrically connected to the electrically conductive channel; a substrate voltage stabilization circuit comprising a first current driven HEMT (high electron mobility transistor) electrically connected between the first input-output terminal and the substrate region and having a gate diode, and a second current driven HEMT electrically connected between the second input-output terminal and the substrate region and having a gate diode; and a gate current control circuit configured, for the current driven HEMT electrically connected to the input-output terminal at a higher voltage, to maintain the gate diode of the current driven HEMT at a voltage that is below a forward voltage of the gate diode while the input-output terminal remains at the higher voltage and transitions to a lower voltage.

According to another embodiment of a semiconductor device, the semiconductor device comprises: a semiconductor body comprising an active region and a substrate region; a bidirectional switch comprising a first and a second gate structure each configured to control a conductive state of an electrically conductive channel in the active region; a first and a second input-output terminal each electrically connected to the electrically conductive channel; a substrate voltage stabilization circuit comprising a first current driven HEMT (high electron mobility transistor) electrically connected between the first input-output terminal and the substrate region and having a gate diode, and a second current driven HEMT electrically connected between the second input-output terminal and the substrate region and having a gate diode; a first pulldown device configured to turn off the first current driven HEMT when a voltage of the gate diode of the second current driven HEMT is above a threshold voltage of the first pulldown device; and a second pulldown device configured to turn off the second current driven HEMT when a voltage of the gate diode of the first current driven HEMT is above a threshold voltage of the second pulldown device.

According to another embodiment of a semiconductor device, the semiconductor device comprises: a terminal; a current driven HEMT (high electron mobility transistor) electrically connected to the terminal and having a gate diode; and a gate current control circuit configured to maintain the gate diode of the current driven HEMT at a voltage that is below a forward voltage of the gate diode while the terminal remains at a higher voltage and transitions to a lower voltage.

Those skilled in the art will recognize additional features and advantages upon reading the following detailed description, and upon viewing the accompanying drawings.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a schematic diagram of an embodiment of a semiconductor die that includes a bidirectional switch and a bias structure.

FIG. 2 illustrates a cross-sectional view of an embodiment of the physical implementation of the bidirectional switch in a semiconductor body.

FIG. 3 illustrates voltage waveforms associated with operation of the bidirectional switch.

FIGS. 4-10 illustrate respective schematic diagrams of the bias structure, according to various embodiments.

### DETAILED DESCRIPTION

Embodiments described herein provide a semiconductor device having a bidirectional switch and a bias structure for the gates of the main substrate biasing transistors that limits the quiescent current while ensuring a low-ohmic gate-drive path for fast switching. The bias structure, which may include a substrate voltage stabilization circuit, a pulldown circuit, and/or a gate current control circuit, prevents the gate diode of the corresponding main substrate biasing transistor from becoming conductive, which would otherwise lead to a high quiescent current. The gate diode is instead biased with a novel voltage achieved by a source-follower like topology in combination with a biasing structure.

Described next with reference to the figures are embodiments of the bias structure.

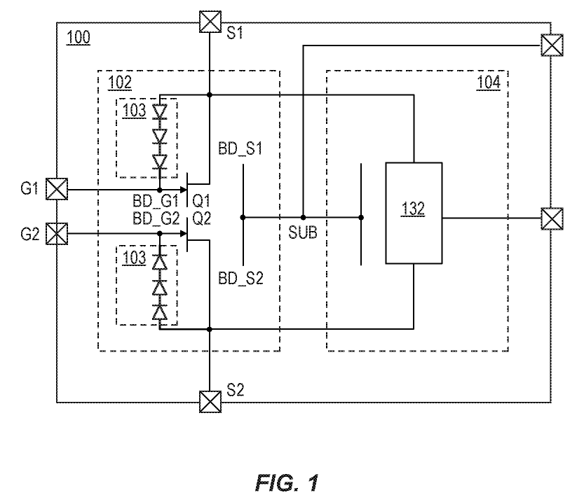

FIG. 1 illustrates a schematic diagram of an embodiment of a semiconductor die 100 that includes a (main) bidirectional switch 102 and a bias structure 104. The main bidirectional switch 100 is formed on a semiconductor substrate which is schematically represented by the node labeled ‘SUB’ in FIG. 1. The main bidirectional switch 100 has first and second gates BD_G1, BD_G2, first and second sources BD_S1, BD_S2, and a common or virtual drain to which there is no physical connection. The gates BD_G1, BD_G2 of the main bidirectional switch 100 may be protected by ESD (electrostatic discharge) protection devices 103 such as ESD diodes. The first source BD_S1 of the main bidirectional switch 100 is electrically connected to a first input-output terminal S1 of the semiconductor die 100. The second source BD_S2 of the main bidirectional switch 100 is electrically connected to a second input-output terminal S2 of the semiconductor die 100.

The main bidirectional switch 100 has four primary operational states: OFF/OFF in which both gates BD_G1, BD_G2 of the main bidirectional switch 100 are off; ON/ON in which both gates BD_G1, BD_G2 of the main bidirectional switch 100 are on; ON/OFF in which the first gate BD_G1 of the main bidirectional switch 100 is on and the second gate BD_G2 of the main bidirectional switch 100 is off; and OFF/ON in which the first gate BD_G1 of the main bidirectional switch 100 is off and the second gate BD_G2 of the main bidirectional switch 100 is on. Typical operation of a bidirectional switch includes transitioning from OFF/OFF to ON/ON, ON/OFF to ON/ON, and from OFF/ON to ON/ON. The current flow direction depends on the polarity across the first and second input-output terminals S1, S2. The current flow direction can be reversed by changing the polarity.

The main bidirectional switch 100 is schematically represented by main transistors Q1 and Q2 in FIG. 1. Main transistors Q1 and Q2 share a common drain and have sources BD_S1, BD_S2 at opposite ends of the main bidirectional switch 100 in the case of a lateral device.

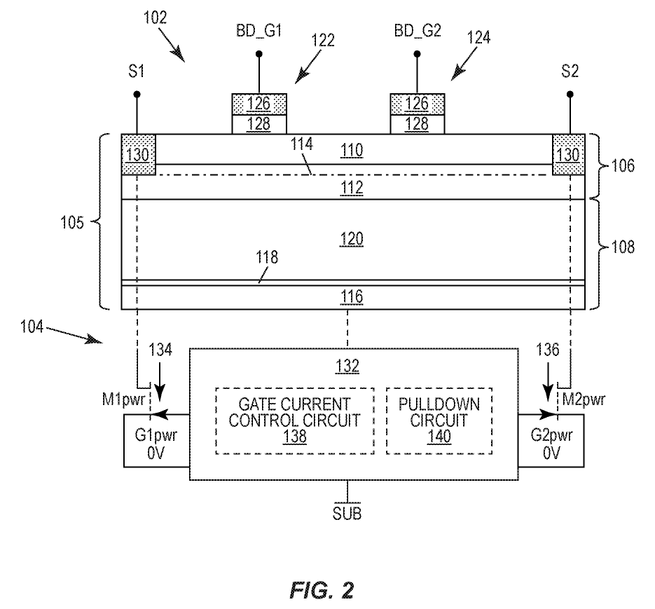

FIG. 2 illustrates a cross-sectional view of an embodiment of the physical implementation of the main bidirectional switch 100 in a semiconductor body 105. The main bidirectional switch 100 may be implemented as a bidirectional HEMT (high-electron mobility transistor) in FIG. 2.

The semiconductor body 105 has an upper active region 106 and a lower (substrate) region 108 that is disposed beneath the active region 106. The active region 106 refers to the layers or regions of the semiconductor body 105 that provide an electrically conductive channel. For example, in the depicted embodiment, the active region 106 includes first and second type III-V semiconductor layers 110, 112. The second type III-V semiconductor layer 112 is formed from a semiconductor material having a different band gap than the first type III-V semiconductor layer 110. For example, the first type III-V semiconductor layer 110 may include intrinsic or lightly doped gallium nitride (GaN) and the second type III-V semiconductor layer 112 may include aluminum gallium nitride (AlGaN). More generally, any combination of type III-V semiconductor materials with different metallic contents can be used to provide a difference in bandgap.

Due to the difference in bandgap between the first and second type III-V semiconductor layers 110, 112, an electrically conductive two-dimensional charge carrier gas channel 114 arises near an interface between the first type III-V semiconductor layer 110 and the second type III-V semiconductor layer 112 due to polarization effects. Alternatively, instead of type III-V semiconductor material, the active region 106 may include group IV semiconductor materials such as Silicon (Si), Silicon carbide (SiC), Silicon germanium (SiGe), etc. The semiconductor materials may be doped to form active device regions, e.g., source, drain, collector, emitter, etc., which provide a controllable electrically conductive channel in a known manner.

The substrate region 108 of the semiconductor body 105 includes various regions of the semiconductor body 105 that do not directly contribute in an electrical sense to the provision of the electrically conductive channel 114. In the depicted embodiment, the substrate region 108 of the semiconductor body 105 includes a substrate 116, a nucleation layer 118, and a lattice transition region 120. The substrate 116 may include or be formed from group IV or group III-V semiconductor materials. For example, according to one embodiment, the substrate 116 may be provided by a silicon or silicon-based wafer. The nucleation layer 118, which may include a metal nitride (e.g., AlN), and the lattice transition region 120, which may include a number of semiconductor nitride (e.g., AlGaN) layers with a gradually diminishing metallic content, are provided on the substrate 116 to enable the formation of relatively strain and defect free group IV semiconductor material thereon. More generally, the substrate 116 may include any intrinsic or bulk semiconductor material that is beneath the active region 106, and is more conductive than an intermediary region that is between the substrate 116 and the active region 106.

The main bidirectional switch 100 may be operated as follows. At a first voltage polarity, in which the second input-output terminal S2 is at a higher potential than the first input-output terminal S1, voltage blocking is primarily handled by a first gate structure 122. That is, an “OFF” signal applied to the first gate structure 122 (e.g., 0V, relative to the first input-output terminal S1) disrupts the channel 114 and causes the main bidirectional switch 100 to be in a blocking mode. The main bidirectional switch 100 becomes conductive by applying an “ON” signal (e.g., a positive voltage, relative to the first input-output terminal S1) to the first gate structure 122, which places the channel 114 in a conductive state. At a second voltage polarity, in which the first input-output terminal S1 is at a higher potential than the second input-output terminal S2, the opposite condition applies. That is, voltage blocking is primarily handled by a second gate structure 124. In this way, the main bidirectional switch 100 can block or permit a current to flow in either direction between the first and second input-output terminals S1, S2. The main bidirectional switch 100 may have symmetrical voltage blocking capability at either voltage polarity. Alternatively, the main bidirectional switch 100 may be configured to have a greater voltage blocking capability at one of the two voltage polarities. This may be achieved by, among other things, adjusting the distance between the first and second gate structures 122, 124 and the first and second input-output terminals S1, S2.

The first and second gate structures 122, 124 may each include an electrically conductive gate electrode 126. According to one embodiment, the first and second gate structures 122, 124 may each also include an intermediary region 128 configured (e.g., by doping) to provide an integrated diode in the respective gate structures 122, 124, also referred to herein as gate diodes. In the case of a type III-V semiconductor device, the first and second gate structures 122, 124 may be configured to alter the intrinsically conductive state of the two-dimensional charge carrier gas channel 114 in the active region 106 of the semiconductor body 105. The first and second input-output terminals S1, S2 are each electrically connected to the electrically conductive channel 114, at the respective source BD_S1, BD_S2 of the main bidirectional switch 100.

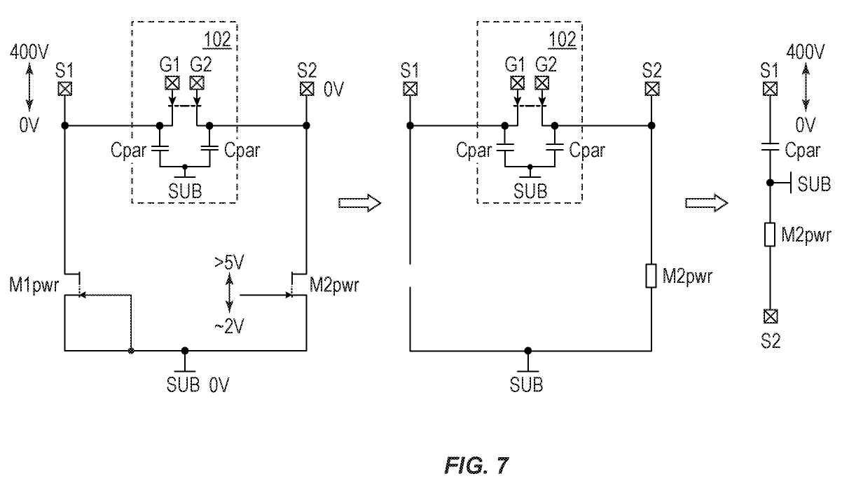

One problem associated with a bidirectional switch that is integrated into a single substrate 105, as is the case in the device of FIG. 2, is the so-called ‘common substrate’ problem. In the absence of any further measures, a parasitic capacitive coupling (see ‘Cpar’ in FIG. 7) occurs between the first and second input-output terminals S1, S2 and the substrate region 108. If the substrate region 108 is not adequately discharged, the voltages across these parasitic capacitances can vary during the operation of the device, which may degrade the channel 114 and affect the switching behavior during operation of the main bidirectional switch 100. In a conventional unidirectional device, this problem is typically solved by tying the substrate of the device to the same potential as the reference potential terminal (e.g., the source terminal) and thus shunting one side of the parasitic substrate capacitance. However, this solution is not available in a bidirectional device because there is no dedicated reference potential terminal. That is, the first input-output terminal S1 acts as the reference potential at one voltage polarity whereas the second input-output terminal S2 acts as the reference potential at the opposite voltage polarity.

The bias structure 104, which is electrically connected in parallel with the main bidirectional switch 102, e.g., at respective ohmic contact regions 130 of the main bidirectional switch 100, discharges the voltage of the substrate region 116 in both directions of the main bidirectional switch 102. In FIGS. 1 and 2, the bias structure 104 includes a substrate voltage stabilization circuit 132. The substrate voltage stabilization circuit 132 includes a first substrate biasing transistor M1pwr electrically connected between the first input-output terminal S1 and the substrate region 108. The substrate voltage stabilization circuit 132 also includes a second substrate biasing transistor M2pwr electrically connected between the second input-output terminal S1 and the substrate region 108. In one embodiment, the first and second substrate biasing transistors M1pwr, M2pwr are current driven HEMTs each with a gate diode 134, 136, respectively.

The gate diodes 134, 136 of the substrate biasing transistors M1pwr, M2pwr can be viewed as diodes integrated in the respective gate structures of the substrate biasing transistors M1pwr, M2pwr. Such a normally-off GaN-based transistor structure is referred to herein as a gate injection transistor (GIT). The substrate biasing transistors M1pwr, M2pwr may be GITs and the gate diodes 132, 134 of the substrate biasing transistors M1pwr, M2pwr may utilize hole-injection from a p-GaN region to an AlGaN/GaN heterojunction, which simultaneously increases electron density in the channel, to yield a dramatic increase in drain current due to conductivity modulation. According to this embodiment, the gates G1pwr, G2pwr of the substrate biasing transistors M1pwr, M2pwr effectively behave like a diode (i.e., current driven) as opposed to the gate of a power MOSFET which is voltage driven. GIT HEMTs offer robust gate performance with a self-clamping mechanism. However, GIT HEMTs require a small current to be injected into the gate to enable conductivity modulation, which can lead to high quiescent current under blocking conditions.

In FIGS. 1 and 2, the bias structure 104 also includes a gate current control circuit 138. For the substrate biasing transistor M1pwr/M2pwr electrically connected to the input-output terminal S1/S2 at the higher voltage, the gate current control circuit 138 maintains the gate diode 134/136 of the substrate biasing transistor M1pwr/M2pwr at a voltage that is below a forward voltage Vf of the gate diode 134/136 while the input-output terminal S1/S2 remains at the higher voltage and transitions to a lower voltage, thereby limiting quiescent current while ensuring a low-ohmic gate-drive path for fast switching.

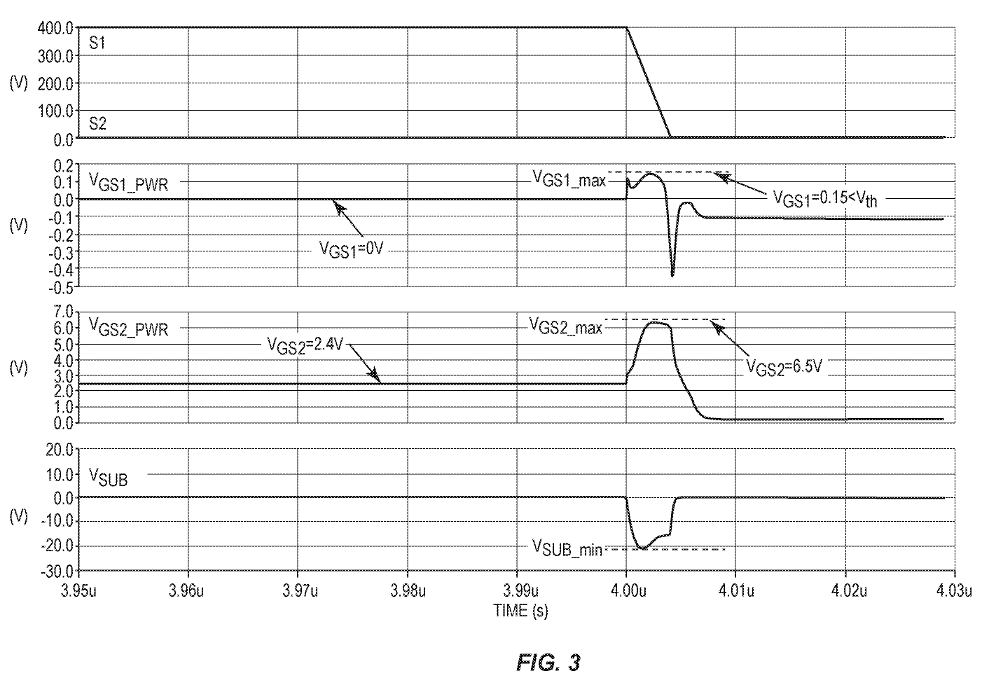

FIG. 3 illustrates voltage waveforms associated with the first input-output terminal S1 being at the higher voltage (400V in the illustrated example) and transitioning to a lower voltage (0V in the illustrated example). The second input-output terminal S2 remains at the lower voltage throughout the portion of the simulation shown in FIG. 3. In this example, the gate current control circuit 138 maintains the gate diode 134 of the first substrate biasing transistor M1pwr at a gate-to-source voltage V_{GS1_PWR} that is below a forward voltage Vf of the gate diode 134 while the first input-output terminal S1 remains at the higher voltage and transitions to the lower voltage.

This approach ensures that the first substrate biasing transistor M1pwr is off when the first input-output terminal S1 is at the higher voltage and transitions to the lower voltage, resulting in little or no quiescent current. Both the gate-to-source voltage V_{GS1_PWR} of the first substrate biasing transistor M1pwr and the gate-to-source voltage V_{GS1} applied to the first gate BD_G1 of the main bidirectional switch 100 are at 0V when the first input-output terminal S1 is at 400V. When the first input-output terminal S1 transitions down to 0V, the gate-to-source voltage V_{GS1_PWR} of the first substrate biasing transistor M1pwr is limited to a maximum value of V_{GS1_max}, which is Vf-Vth (0.15V in this example) where Vf is the forward voltage of the gate diode 134 of the first substrate biasing transistor M1pwr and Vth is the threshold voltage of the first substrate biasing transistor M1pwr.

The second substrate biasing transistor M2pwr remains on during the entire simulation period shown in FIG. 3, to ensure that the substrate region 108 is pinned to the voltage Vs2 (e.g., 0V in this example) of the second input-output terminal S2. That is, the gate current control circuit 138 maintains the gate diode 136 of the second substrate biasing transistor M2pwr at a voltage that is above the forward voltage Vf of the gate diode 136 while the first input-output terminal S1 remains at the higher voltage and transitions to the lower voltage.

In the illustrated example, the gate-to-source voltage V_{GS2_PWR} of the second substrate biasing transistor M2pwr is at 2.4V when the first input-output terminal S1 is at 400V. When the first input-output terminal S1 transitions down to 0V, the gate-to-source voltage V_{GS2_PWR} of the second substrate biasing transistor M2pwr rises to a maximum value V_{GS2_max}, which corresponds to the gate-to-source voltage V_{GS2} of the second gate BD_G2 of the main bidirectional switch 100 and is 6.5V in this example. This causes a slight negative excursion in the substrate voltage V_{SUB} to a value V_{SUB_min} during the transition in the voltage at the first input-output terminal S1.

When the second input-output terminal S2 is at the higher voltage and transitions to the lower voltage, the S1, S2, V_{GS1_PWR}, and V_{GS2_PWR} voltage waveforms are reversed but the substrate voltage waveform is the same, except that the first substrate biasing transistor M1pwr performs the substrate voltage pinning function instead of the second substrate biasing transistor M2pwr. In either case, the gate current control circuit 138 maintains the gate-to-source voltage V_{GS1_PWR}/V_{GS2_PWR} of the substrate biasing transistor M1pwr/M2pwr that is off (i.e., not pinning the substrate voltage V_{SUB}) to a voltage (Vf-Vth) that is below the gate diode forward voltage Vf.

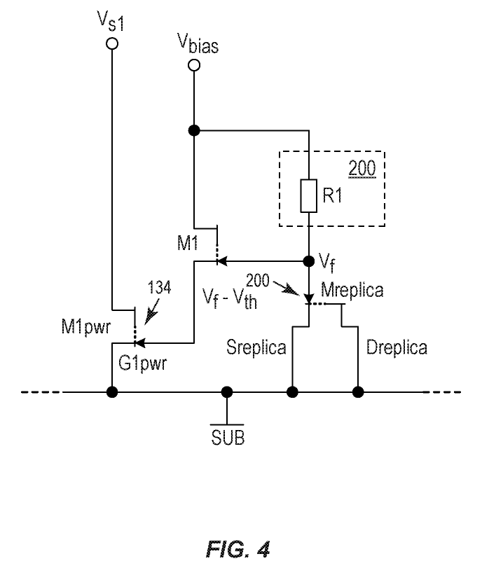

FIG. 4 illustrates an embodiment of the gate current control circuit 138, for the first substrate biasing transistor M1pwr. In FIG. 4, the gate current control circuit 138 includes a first enhancement mode (i.e., off at zero gate–source voltage) HEMT M1 electrically connected to the gate diode 134 of the first substrate biasing transistor M1pwr and a gate biasing device Mreplica. The gate biasing device Mreplica biases the gate diode 134 of the first substrate biasing transistor M1pwr, and the gate voltage of the first enhancement mode HEMT M1 controls the gate biasing device Mreplica. When the first substrate biasing transistor M1pwr is off, the first enhancement mode HEMT M1 and the gate biasing device Mreplica maintain the gate-to-source voltage V_{GS1_PWR} of the first substrate biasing transistor M1pwr to a voltage (Vf-Vth) that is below the forward voltage Vf of the gate diode 134 of the first substrate biasing transistor M1pwr.

The gate current control circuit implementation shown in FIG. 4 may be mirrored for the second substrate biasing transistor M2pwr. That is, a second enhancement mode HEMT M2 (not shown in FIG. 4) can be electrically connected to the gate diode 136 of the second substrate biasing transistor M2pwr and a second gate biasing device (not shown in FIG. 4) can be provided to bias the gate diode 136 of the second substrate biasing transistor M2pwr, where the gate voltage of the second enhancement mode HEMT M2 controls the second gate biasing device.

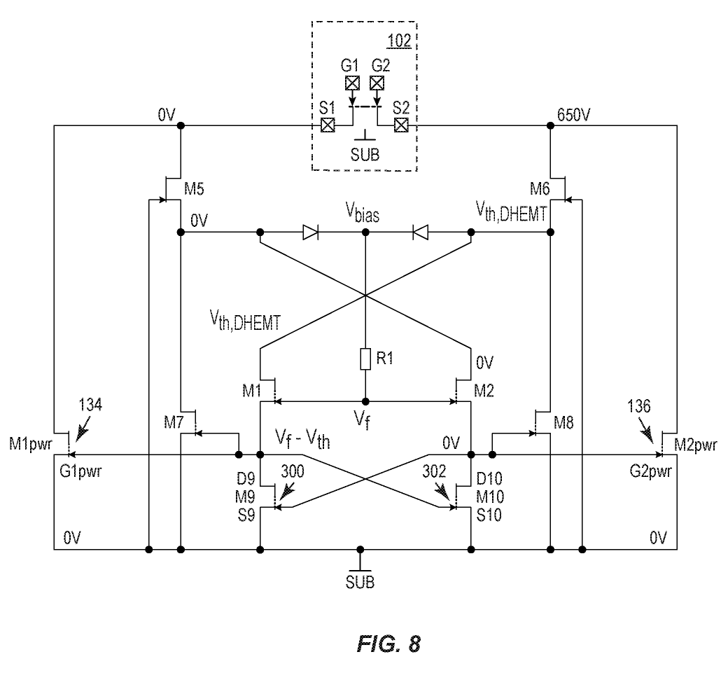

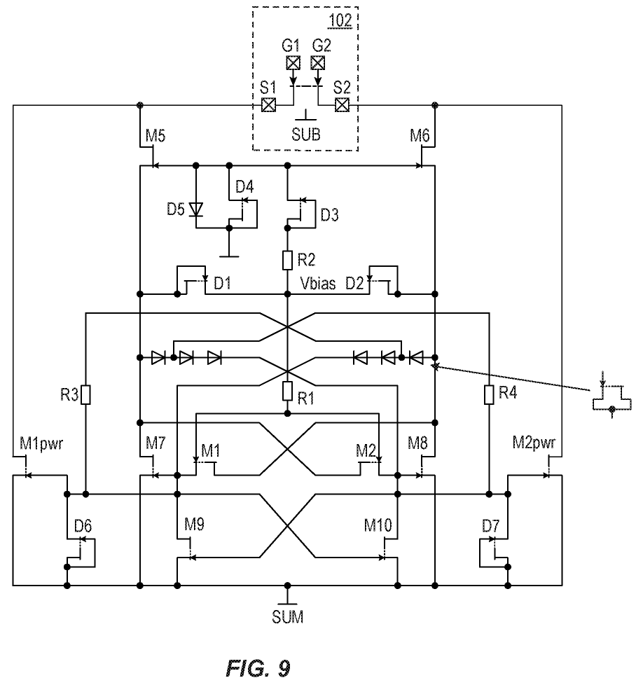

The gate biasing device Mreplica of the gate current control circuit 138 may be implemented as a current driven HEMT having a source Sreplica and a drain Dreplica both electrically connected to the substrate region 108 and a gate diode 200 electrically connected to both the gate of the corresponding enhancement mode HEMT M1/M2 and a device 200 that limits the gate current of the corresponding enhancement mode HEMT M1/M2. In FIG. 4, the device 200 that limits the gate current of the first enhancement mode HEMT M1 is a resistor R1. The resistor R1 may be common to both enhancement mode HEMTs M1, M2, such that the same resistor R1 limits both the gate current of the first enhancement mode HEMT M1 and the gate current of the second enhancement mode HEMT M2 (see FIGS. 8 and 9).

With a current into the gate of the first enhancement mode HEMT M1, which is limited by the first resistor R1, a voltage is generated right at the gate-diode forward voltage Vf. This voltage serves as a gate voltage on the gate biasing device Mreplica, which functions as a source-follower in FIG. 4, to bias the gate G1pwr of the first substrate biasing transistor M1pwr. The gate-to-source voltage V_{GS1_PWR} of the first substrate biasing transistor M1pwr does not rise higher than Vf - Vth in this configuration. As such, the gate diode 134 of the first substrate biasing transistor M1pwr does not start conducting (i.e., does not forward bias). As the gate voltage level is defined, the maximum current consumption of the structure is determined by the first resistor R1 and a bias voltage Vbias. The same voltage behavior applies, mutatis mutandis, for the second substrate biasing transistor M2pwr for voltage blocking in the other direction.

In one embodiment, the forward voltage Vf of the gate diode 200 of the current driven HEMT Mreplica matches the forward voltage Vf of the gate diode 134 of the first substrate biasing transistor M1pwr. Likewise, the forward voltage of the gate diode of a current driven HEMT (not shown in FIG. 4 but could mirror Mreplica) associated with the second substrate biasing transistor M2pwr matches the forward voltage Vf of the gate diode 136 of the second substrate biasing transistor M2pwr.

The gate biasing device Mreplica for the first substrate biasing transistor M1pwr instead may be a first plurality of gated diodes electrically connected in series between the gate of the first enhancement mode HEMT M1 and the substrate region 108. A gated diode (or gate-controlled diode) is a semiconductor device that combines the function of a p-n junction and a MOS capacitor. Likewise, the gate biasing device for the second substrate biasing transistor M2pwr may also be a second plurality of gated diodes electrically connected in series between the gate of the second enhancement mode HEMT M2 and the substrate region 108. According to this embodiment, the forward voltage Vf of the first plurality of gated diodes may match the forward voltage Vf of the gate diode 134 of the first substrate biasing transistor M1pwr and the forward voltage of the second plurality of gated diodes may match the forward voltage Vf of the gate diode 136 of the second substrate biasing transistor M2pwr.

The gate biasing device Mreplica for the first substrate biasing transistor M1pwr instead may be a first pn diode electrically connected between the gate of the first enhancement mode HEMT M1 and the substrate region 108, and the second gate biasing device for the second substrate biasing transistor M2pwr may be a second pn diode electrically connected between the gate of the second enhancement mode M2 and the substrate region 108. According to this embodiment, the forward voltage Vf of the first pn diode may match the forward voltage Vf of the gate diode 134 of the first substrate biasing transistor M1pwr and the forward voltage Vf of the second pn diode may match the forward voltage Vf of the gate diode 136 of the second substrate biasing transistor M2pwr.

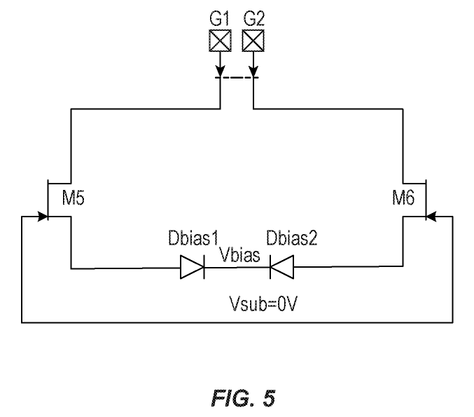

FIG. 5 illustrates an embodiment of a circuit for generating the bias voltage Vbias. The bias voltage generation circuit includes two depletion mode (normally on at zero gate–source voltage) HEMT cascode devices M5, M6 and two diodes Dbias1, Dbias2, which form a maximum selector circuit. The bias voltage Vbias is always present as soon as there is a certain voltage difference between the two source nodes BD_S1, BD_S2 of the main bidirectional switch 102. The bias voltage Vbias ensures proper biasing of the first enhancement mode HEMT M1, the gate biasing device Mreplica, and the substrate biasing transistors M1pwr, M2pwr.

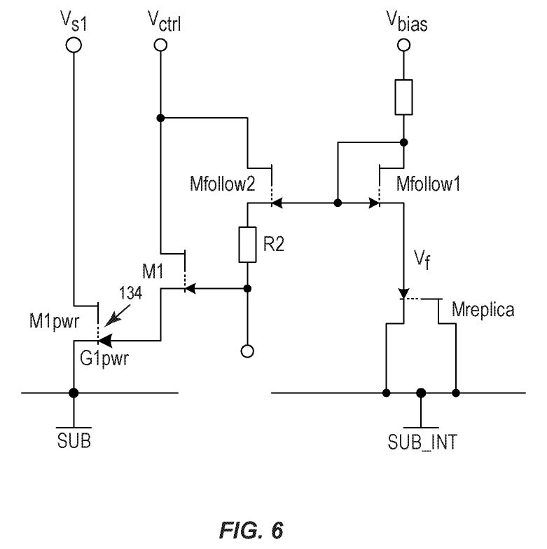

FIG. 6 illustrates another embodiment of the gate current control circuit 138, for the first substrate biasing transistor M1pwr. In FIG. 6, the gate current control circuit 138 includes a source follower device Mfollow1 that limits the gate current of the first enhancement mode HEMT M1. The gate current control circuit implementation shown in FIG. 6 may be mirrored for the second substrate biasing transistor M2pwr. That is, the gate current control circuit 138 may include another source follower device that limits the gate current of the second enhancement mode HEMT M2.

In FIG. 6, the gate current control circuit 138 also includes the first resistor R1 electrically connected between the first bias voltage node Vbias and the drain of the source follower device Mfollow1 and a second resistor R2 that helps limit the gate current of the first enhancement mode HEMT M1. As explained above, the gate current control circuit implementation shown in FIG. 6 may be mirrored for the second substrate biasing transistor M2pwr. Accordingly, a third resistor (not shown in FIG. 6) may be provided for limiting the gate current of the second enhancement mode HEMT M2 (also not shown in FIG. 6). In one embodiment, the first resistor R1 has a resistance that is at least one order of magnitude greater than the resistance of the second resistor R2 and the resistance of the third resistor R3.

A second source follower device Mfollow2 may be electrically connected between a control node Vctrl and the drain of the first enhancement mode HEMT M1, with the gate of both source follower devices Mfollow1, Mfollow2 being biased the same way via the first resistor R1. If the control input Vctrl is inactive, current that flows into the gate of the gate biasing device Mreplica is low. If the control input Vctrl changes, the source follower arrangement in FIG. 6 strongly drives the gate of the gate biasing device Mreplica. If the drain of the gate biasing device Mreplica is driven to a high voltage, then a low ohmic path is enabled and a classic source follower is realized. The biasing of the gate biasing device Mreplica determines the current into the gate G1pwr of the first substrate biasing transistor M1pwr. The gate biasing device Mreplica may be biased such that the gate biasing device Mreplica is on but current into the gate of the first enhancement mode HEMT M1 is almost zero. If the voltage (biasing) is higher, the gate diode forward biases and current into the gate of the first enhancement mode HEMT M1 increases exponentially. The same source follower arrangement may be mirrored to limit the gate current of the second enhancement mode HEMT M2.

In steady state, the voltage at the gate G1pwr of the first substrate biasing transistor M1pwr is Vf – Vth, where Vf is the forward voltage of the gate diode 134 of the first substrate biasing transistor M1pwr and Vth is the threshold voltage of the first substrate biasing transistor M1pwr. Accordingly, the gate G1pwr of the first substrate biasing transistor M1pwr remains at or near the off gate voltage Vgs,off (e.g., 0.5V) instead of a sub-threshold or near-threshold voltage (e.g., ~1V) during the voltage blocking state. During transients, the voltage at the gate G1pwr of the first substrate biasing transistor M1pwr is Vf - Vth + (V_{SUB_INT} - V_{SUB}), where V_{SUB} is the voltage of the substrate region 108 and V_{SUB_INT} is the voltage of an intermediate substrate region SUB_INT to which the gate biasing device Mreplica is referenced. The biasing embodiment illustrated in FIG. 6 yields much higher overdrive of the substrate biasing transistors M1pwr, M2pwr during transients and is much more area efficient.

FIG. 7 illustrates that the gate current control circuit 138 embodiment illustrated in FIG. 6 supports both hard and soft switching. Hard switching involves commutation implemented by means of resistive and reactive paths. Soft switching involves commutation implemented by means of reactive paths only (e.g., power inductors).

The lefthand schematic of FIG. 7 shows a switching example where the first input-output terminal S1 transitions from 400V to 0V while the second input-output terminal S2 remains at 0V, with the parasitic gate-source capacitance Cpar shown as two capacitors for each half of the main bidirectional switch 102. In this example, the first substrate biasing transistor M1pwr is off and the second substrate biasing transistor M2pwr is on. The middle schematic of FIG. 7 is a simplified representation, with the first substrate biasing transistor M1pwr appearing as an open circuit and the second substrate biasing transistor M2pwr appearing as a resistive or reactive component. The righthand schematic of FIG. 7 shows the equivalent circuit that actively stabilizes the substrate region 108 in this example.

The second substrate biasing transistor M2pwr pins the substrate region 108 to 0V, which is the voltage at the second input-output terminal S2. The gate-to-source voltage V_{GS2_PWR} of the second substrate biasing transistor M2pwr fluctuates when the first input-output terminal S1 transitions from 400V to 0V, as previously explained herein, e.g., between about 2V to less than 5V. This will cause slight but tolerable perturbation of the substrate voltage V_{SUB}, while ensuring a low-ohmic gate-drive path for fast switching. For soft switching, the substrate biasing transistors M1pwr, M2pwr should be as low-ohmic as possible to yield better reliability and system efficiency.

Returning to FIG. 2, the bias structure 104 integrated in the same semiconductor die 100 as the main bidirectional switch 102 may include a pulldown circuit 140 that turns off the first substrate biasing transistor M1pwr or the second substrate biasing transistor M2pwr under certain voltage conditions. The semiconductor die 100 may include any combination of the substrate voltage stabilization circuit 132, the gate current control circuit 138 and the pulldown circuit 140. That is, the semiconductor die 100 may include any one, two or three of the substrate voltage stabilization circuit 132, the gate current control circuit 138 and the pulldown circuit 140.

FIG. 8 illustrates another embodiment of the bias structure 104 integrated in the same semiconductor die 100 as the main bidirectional switch 102. In FIG. 8, the pulldown circuit 140 includes a first pulldown device M9 and a second pulldown device M10. The first pulldown device M9 turns off the first substrate biasing transistor M1pwr when the gate-to-source voltage V_{GS2_PWR} of the second substrate biasing transistor M2pwr is above the threshold voltage Vth of the first pulldown device M9. The second pulldown device M10 turns off the second substrate biasing transistor M2pwr when the gate-to-source voltage V_{GS1_PWR} of the first substrate biasing transistor M1pwr is above the threshold voltage Vth of the second pulldown device M10. In other words, the first and second pulldown devices M9, M10 act as latches to clamp the gate-to-source voltages V_{GS1_PWR}, V_{GS2_PWR} of the substrate biasing transistors M1pwr, M2pwr, respectively, according to the voltages at the input-output terminals S1, S2.

In one embodiment, the pulldown devices M9, M10 are GIT HEMTs. For example, the first pulldown device M9 may be a current driven HEMT having a drain D9 electrically connected to the gate diode 134 of the first substrate biasing transistor M1pwr, a source S9 electrically connected to the substrate region 108 and a gate diode 300 electrically connected to the gate diode 136 of the second substrate biasing transistor M2pwr. Likewise, the second pulldown device M10 may be a current driven HEMT having a drain D10 electrically connected to the gate diode 136 of the second substrate biasing transistor M2pwr, a source S10 electrically connected to the substrate region 108 and a gate diode 302 electrically connected to the gate diode 134 of the first substrate biasing transistor M1pwr.

Example voltage levels are overlaid in the circuit of FIG. 8, where in the illustrated example the first input-output terminal S1 is at 0V and the second input-output terminal S2 is at 650V. At these conditions for S1 and S2, the gate diode 302 of the second pulldown device M10 is biased at 0V and the gate diode 300 of the first pulldown device M9 is biased at a positive voltage V_{th,dHEMT}. Devices M1 and M2 are enhancement mode HEMTs that create the Vf-Vth voltage for biasing the gates G1pwr, G2pwr of the substrate biasing transistors M1pwr, M2pwr. Devices M5 and M6 are depletion mode HEMTs that act as cascode devices to provide the bias voltage Vbias. Devices M7 and M8 are enhancement mode HEMTs that, in combination with devices M5 and M6, act as a minimum selector. Devices M9 and M10 are enhancement mode HEMTs that function latches to clamp the gates G1pwr, G2pwr of the substrate biasing transistors M1pwr, M2pwr according to the voltages on the sources BD_S1, BD_S2 of the main bidirectional switch 102.

FIG. 9 illustrates another embodiment of the bias structure 104 integrated in the same semiconductor die 100 as the main bidirectional switch 102. In FIG. 9, diode devices D3, D4 and D5 in conjunction with resistor R2 raise the gate voltage to a Vf diode voltage above the substrate voltage V_{SUB} and hence increase the bias voltage Vbias accordingly. If the substrate voltage V_{SUB} is higher than both the lowest source voltage (Vs1 or Vs2) and the gate voltage V_{GSn_PWR} of the corresponding substrate biasing transistor Mnpwr, diode devices D6 and D7 conduct and turn on that substrate biasing transistor Mnpwr. Resistors R3 and R4 raise the gate voltage V_{GS1_PWR}, V_{GS2_PWR} of the substrate biasing transistors M1pwr, M2pwr, respectively, even further.

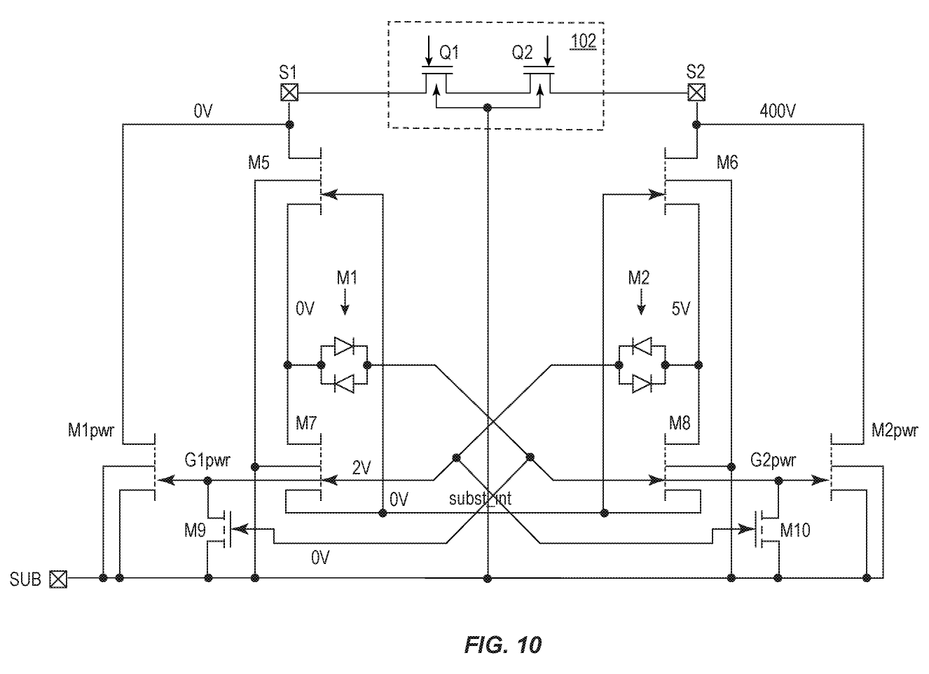

FIG. 10 illustrates another embodiment of the bias structure 104 integrated in the same semiconductor die 100 as the main bidirectional switch 102. FIG. 10 shows the addition of the pulldown devices M9, M10 in the substrate potential stabilization circuit 132. Example voltage levels are overlaid in the circuit of FIG. 10, where in the illustrated example the first input-output terminal S1 is at 0V and the second input-output terminal S2 is at 400V.

Although the present disclosure is not so limited, the following numbered examples demonstrate one or more aspects of the disclosure.

Example 1. A semiconductor device, comprising: a semiconductor body comprising an active region and a substrate region; a bidirectional switch comprising a first and a second gate structure each configured to control a conductive state of an electrically conductive channel in the active region; a first and a second input-output terminal each electrically connected to the electrically conductive channel; a substrate voltage stabilization circuit comprising a first current driven HEMT (high electron mobility transistor) electrically connected between the first input-output terminal and the substrate region and having a gate diode, and a second current driven HEMT electrically connected between the second input-output terminal and the substrate region and having a gate diode; and a gate current control circuit configured, for the current driven HEMT electrically connected to the input-output terminal at a higher voltage, to maintain the gate diode of the current driven HEMT at a voltage that is below a forward voltage of the gate diode while the input-output terminal remains at the higher voltage and transitions to a lower voltage.

Example 2. The semiconductor device of example 1, wherein the gate current control circuit is configured, for the current driven HEMT electrically connected to the input-output terminal at the lower voltage, to maintain the gate diode of the current driven HEMT at a voltage that is above a forward voltage of the gate diode while the other input-output terminal remains at the higher voltage and transitions to the lower voltage.

Example 3. The semiconductor device of example 1 or 2, wherein the gate current control circuit comprises: a first enhancement mode HEMT electrically connected to the gate diode of the first current driven HEMT; a first gate biasing device configured to bias the gate diode of the first current driven HEMT, wherein a gate voltage of the first enhancement mode HEMT controls the first gate biasing device; a second enhancement mode HEMT electrically connected to the gate diode of the second current driven HEMT; and a second gate biasing device configured to bias the gate diode of the second current driven HEMT, wherein a gate voltage of the second enhancement mode HEMT controls the second gate biasing device.

Example 4. The semiconductor device of example 3, wherein the first gate biasing device comprises a third current driven HEMT having a source and a drain both electrically connected to the substrate region and a gate diode electrically connected to both the gate of the first enhancement mode HEMT and a device configured to limit a gate current of the first enhancement mode HEMT, and wherein the second gate biasing device comprises a fourth current driven HEMT having a source and a drain both electrically connected to the substrate region and a gate diode electrically connected to both the gate of the second enhancement mode HEMT and a device configured to limit a gate current of the second enhancement mode HEMT.

Example 5. The semiconductor device of example 4, wherein a forward voltage of the gate diode of the third current driven HEMT matches the forward voltage of the gate diode of the first current driven HEMT, and wherein a forward voltage of the gate diode of the fourth current driven HEMT matches the forward voltage of the gate diode of the second current driven HEMT.

Example 6. The semiconductor device of example 3, wherein the first gate biasing device comprises a first plurality of gated diodes electrically connected in series between the gate of the first enhancement mode HEMT and the substrate region, and wherein the second gate biasing device comprises a second plurality of gated diodes electrically connected in series between the gate of the second enhancement mode HEMT and the substrate region.

Example 7. The semiconductor device of example 6, wherein a forward voltage of the first plurality of gated diodes matches the forward voltage of the gate diode of the first current driven HEMT, and wherein a forward voltage of the second plurality of gated diodes matches the forward voltage of the gate diode of the second current driven HEMT.

Example 8. The semiconductor device of example 3, wherein the first gate biasing device comprises a first pn diode electrically connected between the gate of the first enhancement mode HEMT and the substrate region, and wherein the second gate biasing device comprises a second pn diode electrically connected between the gate of the second enhancement mode HEMT and the substrate region.

Example 9. The semiconductor device of example 8, wherein a forward voltage of the first pn diode matches the forward voltage of the gate diode of the first current driven HEMT, and wherein a forward voltage of the second pn diode matches the forward voltage of the gate diode of the second current driven HEMT.

Example 10. The semiconductor device of any of examples 3 through 9, wherein the gate current control circuit further comprises: a resistor configured to limit a gate current of the first enhancement mode HEMT and to limit a gate current of the second enhancement mode HEMT.

Example 11. The semiconductor device of any of examples 3 through 10, wherein the gate current control circuit further comprises: a source follower device configured to limit a gate current of the first enhancement mode HEMT and to limit a gate current of the second enhancement mode HEMT.

Example 12. The semiconductor device of example 11, wherein the gate current control circuit further comprises: a first resistor electrically connected between a first bias voltage node and a drain of the source follower device; a second resistor configured to help limit the gate current of the first enhancement mode HEMT; and a third resistor configured to help limit the gate current of the second enhancement mode HEMT.

Example 13. The semiconductor device of example 12, wherein the first resistor has a resistance that is at least one order of magnitude greater than a resistance of the second resistor and a resistance of the third resistor.

Example 14. The semiconductor device of any of examples 1 through 13, further comprising: a first pulldown device configured to turn off the first current driven HEMT when a voltage of the gate diode of the second current driven HEMT is above a threshold voltage of the first pulldown device; and a second pulldown device configured to turn off the second current driven HEMT when a voltage of the gate diode of the first current driven HEMT is above a threshold voltage of the second pulldown device.

Example 15. The semiconductor device of example 14, wherein the first pulldown device comprises a third current driven HEMT having a drain electrically connected to the gate diode of the first current driven HEMT, a source electrically connected to the substrate region and a gate diode electrically connected to the gate diode of the second current driven HEMT, and wherein the second pulldown device comprises a fourth current driven HEMT having a drain electrically connected to the gate diode of the second current driven HEMT, a source electrically connected to the substrate region and a gate diode electrically connected to the gate diode of the first current driven HEMT.

Example 16. A semiconductor device, comprising: a semiconductor body comprising an active region and a substrate region; a bidirectional switch comprising a first and a second gate structure each configured to control a conductive state of an electrically conductive channel in the active region; a first and a second input-output terminal each electrically connected to the electrically conductive channel; a substrate voltage stabilization circuit comprising a first current driven HEMT (high electron mobility transistor) electrically connected between the first input-output terminal and the substrate region and having a gate diode, and a second current driven HEMT electrically connected between the second input-output terminal and the substrate region and having a gate diode; a first pulldown device configured to turn off the first current driven HEMT when a voltage of the gate diode of the second current driven HEMT is above a threshold voltage of the first pulldown device; and a second pulldown device configured to turn off the second current driven HEMT when a voltage of the gate diode of the first current driven HEMT is above a threshold voltage of the second pulldown device.

Example 17. The semiconductor device of example 16, wherein the first pulldown device comprises a third current driven HEMT having a drain electrically connected to the gate diode of the first current driven HEMT, a source electrically connected to the substrate region and a gate diode electrically connected to the gate diode of the second current driven HEMT, and wherein the second pulldown device comprises a fourth current driven HEMT having a drain electrically connected to the gate diode of the second current driven HEMT, a source electrically connected to the substrate region and a gate diode electrically connected to the gate diode of the first current driven HEMT.

Example 18. A semiconductor device, comprising: a terminal; a current driven HEMT (high electron mobility transistor) electrically connected to the terminal and having a gate diode; and a gate current control circuit configured to maintain the gate diode of the current driven HEMT at a voltage that is below a forward voltage of the gate diode while the terminal remains at a higher voltage and transitions to a lower voltage.

Example 19. The semiconductor device of example 18, wherein the gate current control circuit comprises: an enhancement mode HEMT electrically connected to the gate diode of the current driven HEMT; and a gate biasing device configured to bias the gate diode of the current driven HEMT, wherein a gate voltage of the enhancement mode HEMT controls the gate biasing device.

Example 20. The semiconductor device of example 19, wherein the gate biasing device comprises an additional current driven HEMT having a source and a drain both electrically connected to the substrate region and a gate diode electrically connected to both the gate of the enhancement mode HEMT and a device configured to limit a gate current of the first enhancement mode HEMT, and wherein a forward voltage of the gate diode of the additional current driven HEMT matches the forward voltage of the gate diode of the current driven HEMT.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising:
a semiconductor body comprising an active region and a substrate region;
a bidirectional switch comprising a first and a second gate structure each configured to control a conductive state of an electrically conductive channel in the active region;
a first and a second input-output terminal each electrically connected to the electrically conductive channel;
a substrate voltage stabilization circuit comprising a first current driven HEMT (high electron mobility transistor) electrically connected between the first input-output terminal and the substrate region and having a gate diode, and a second current driven HEMT electrically connected between the second input-output terminal and the substrate region and having a gate diode; and
a gate current control circuit configured, for the current driven HEMT electrically connected to the input-output terminal at a higher voltage, to maintain the gate diode of the current driven HEMT at a voltage that is below a forward voltage of the gate diode while the input-output terminal remains at the higher voltage and transitions to a lower voltage.

2. The semiconductor device of claim 1, wherein the gate current control circuit is configured, for the current driven HEMT electrically connected to the input-output terminal at the lower voltage, to maintain the gate diode of the current driven HEMT at a voltage that is above a forward voltage of the gate diode while the other input-output terminal remains at the higher voltage and transitions to the lower voltage.

3. The semiconductor device of claim 1, wherein the gate current control circuit comprises:
a first enhancement mode HEMT electrically connected to the gate diode of the first current driven HEMT;
a first gate biasing device configured to bias the gate diode of the first current driven HEMT, wherein a gate voltage of the first enhancement mode HEMT controls the first gate biasing device;
a second enhancement mode HEMT electrically connected to the gate diode of the second current driven HEMT; and
a second gate biasing device configured to bias the gate diode of the second current driven HEMT, wherein a gate voltage of the second enhancement mode HEMT controls the second gate biasing device.

4. The semiconductor device of claim 3, wherein the first gate biasing device comprises a third current driven HEMT having a source and a drain both electrically connected to the substrate region and a gate diode electrically connected to both the gate of the first enhancement mode HEMT and a device configured to limit a gate current of the first enhancement mode HEMT, and wherein the second gate biasing device comprises a fourth current driven HEMT having a source and a drain both electrically connected to the substrate region and a gate diode electrically connected to both the gate of the second enhancement mode HEMT and a device configured to limit a gate current of the second enhancement mode HEMT.

5. The semiconductor device of claim 4, wherein a forward voltage of the gate diode of the third current driven HEMT matches the forward voltage of the gate diode of the first current driven HEMT, and wherein a forward voltage of the gate diode of the fourth current driven HEMT matches the forward voltage of the gate diode of the second current driven HEMT.

6. The semiconductor device of claim 3, wherein the first gate biasing device comprises a first plurality of gated diodes electrically connected in series between the gate of the first enhancement mode HEMT and the substrate region, and wherein the second gate biasing device comprises a second plurality of gated diodes electrically connected in series between the gate of the second enhancement mode HEMT and the substrate region.

7. The semiconductor device of claim 6, wherein a forward voltage of the first plurality of gated diodes matches the forward voltage of the gate diode of the first current driven HEMT, and wherein a forward voltage of the second plurality of gated diodes matches the forward voltage of the gate diode of the second current driven HEMT.

8. The semiconductor device of claim 3, wherein the first gate biasing device comprises a first pn diode electrically connected between the gate of the first enhancement mode HEMT and the substrate region, and wherein the second gate biasing device comprises a second pn diode electrically connected between the gate of the second enhancement mode HEMT and the substrate region.

9. The semiconductor device of claim 8, wherein a forward voltage of the first pn diode matches the forward voltage of the gate diode of the first current driven HEMT, and wherein a forward voltage of the second pn diode matches the forward voltage of the gate diode of the second current driven HEMT.

10. The semiconductor device of claim 3, wherein the gate current control circuit further comprises:
a resistor configured to limit a gate current of the first enhancement mode HEMT and to limit a gate current of the second enhancement mode HEMT.

11. The semiconductor device of claim 3, wherein the gate current control circuit further comprises:
a source follower device configured to limit a gate current of the first enhancement mode HEMT and to limit a gate current of the second enhancement mode HEMT.

12. The semiconductor device of claim 11, wherein the gate current control circuit further comprises:
a first resistor electrically connected between a first bias voltage node and a drain of the source follower device;
a second resistor configured to help limit the gate current of the first enhancement mode HEMT; and
a third resistor configured to help limit the gate current of the second enhancement mode HEMT.

13. The semiconductor device of claim 12, wherein the first resistor has a resistance that is at least one order of magnitude greater than a resistance of the second resistor and a resistance of the third resistor.

14. The semiconductor device of claim 1, further comprising:
a first pulldown device configured to turn off the first current driven HEMT when a voltage of the gate diode of the second current driven HEMT is above a threshold voltage of the first pulldown device; and
a second pulldown device configured to turn off the second current driven HEMT when a voltage of the gate diode of the first current driven HEMT is above a threshold voltage of the second pulldown device.

15. The semiconductor device of claim 14, wherein the first pulldown device comprises a third current driven HEMT having a drain electrically connected to the gate diode of the first current driven HEMT, a source electrically connected to the substrate region and a gate diode electrically connected to the gate diode of the second current driven HEMT, and wherein the second pulldown device comprises a fourth current driven HEMT having a drain electrically connected to the gate diode of the second current driven HEMT, a source electrically connected to the substrate region and a gate diode electrically connected to the gate diode of the first current driven HEMT.

16. A semiconductor device, comprising:
a semiconductor body comprising an active region and a substrate region;
a bidirectional switch comprising a first and a second gate structure each configured to control a conductive state of an electrically conductive channel in the active region;
a first and a second input-output terminal each electrically connected to the electrically conductive channel;
a substrate voltage stabilization circuit comprising a first current driven HEMT (high electron mobility transistor) electrically connected between the first input-output terminal and the substrate region and having a gate diode, and a second current driven HEMT electrically connected between the second input-output terminal and the substrate region and having a gate diode;
a first pulldown device configured to turn off the first current driven HEMT when a voltage of the gate diode of the second current driven HEMT is above a threshold voltage of the first pulldown device; and
a second pulldown device configured to turn off the second current driven HEMT when a voltage of the gate diode of the first current driven HEMT is above a threshold voltage of the second pulldown device.

17. The semiconductor device of claim 16, wherein the first pulldown device comprises a third current driven HEMT having a drain electrically connected to the gate diode of the first current driven HEMT, a source electrically connected to the substrate region and a gate diode electrically connected to the gate diode of the second current driven HEMT, and wherein the second pulldown device comprises a fourth current driven HEMT having a drain electrically connected to the gate diode of the second current driven HEMT, a source electrically connected to the substrate region and a gate diode electrically connected to the gate diode of the first current driven HEMT.

18. A semiconductor device, comprising:
a terminal;
a current driven HEMT (high electron mobility transistor) electrically connected to the terminal and having a gate diode; and
a gate current control circuit configured to maintain the gate diode of the current driven HEMT at a voltage that is below a forward voltage of the gate diode while the terminal remains at a higher voltage and transitions to a lower voltage.

19. The semiconductor device of claim 18, wherein the gate current control circuit comprises:
an enhancement mode HEMT electrically connected to the gate diode of the current driven HEMT; and
a gate biasing device configured to bias the gate diode of the current driven HEMT, wherein a gate voltage of the enhancement mode HEMT controls the gate biasing device.

20. The semiconductor device of claim 19, wherein the gate biasing device comprises an additional current driven HEMT having a source and a drain both electrically connected to the substrate region and a gate diode electrically connected to both the gate of the enhancement mode HEMT and a device configured to limit a gate current of the first enhancement mode HEMT, and wherein a forward voltage of the gate diode of the additional current driven HEMT matches the forward voltage of the gate diode of the current driven HEMT.
